(19) United States
(12) Patent Application Publication
(10) Pub. No.: US 2022/0193811 A1
(43) Pub. Date: Jun. 23, 2022

(54) APPARATUS AND METHOD FOR DETECTING THE TEMPERATURE OF A BONDING TOOL DURING LASER-ASSISTED ULTRASONIC BONDING

(71) Applicant: Hesse GmbH, Paderborn (DE)

(72) Inventors: Andreas UNGER, Verl (DE); Michael BROEKELMANN, Delbrueck (DE); Matthias HUNSTIG, Paderborn (DE); Hans-Juergen HESSE, Paderborn (DE)

(73) Assignee: Hesse GmbH, Paderborn (DE)

(21) Appl. No.: 17/691,639

(22) Filed: Mar. 10, 2022

Related U.S. Application Data
(63) Continuation of application No. PCT/DE2020/100782, filed on Sep. 8, 2020.

(30) Foreign Application Priority Data
Sep. 11, 2019 (DE) 10 2019 124 332.7

(51) Int. Cl. B23K 20/10; B23K 20/26

(52) U.S. Cl. CPC B23K 20/10; B23K 20/004; B23K 20/26

(57) ABSTRACT

An apparatus for detecting the temperature of a bonding tool during laser-assisted ultrasonic bonding, comprising an automatic bonding machine having the bonding tool, having a displacement and/or positioning module for the bonding tool and having a device for exciting the bonding tool to ultrasonically vibrate, comprising a laser generator for providing a laser beam, and comprising an optical waveguide for guiding the laser beam from the laser generator to the bonding tool, wherein the optical waveguide has a multi-part design, that a deflecting and beam-splitting unit is provided between at least two adjacent parts of the optical waveguide and that furthermore a temperature sensor is provided.

This nonprovisional application is a continuation of International Application No. PCT/DE2020/100782, which was filed on Sep. 8, 2020, and which claims priority to German Patent Application No. 10 2019 124 332.7, which was filed in Germany on Sep. 11, 2019, and which are both herein incorporated by reference.

### BACKGROUND OF THE INVENTION

### Field of the Invention

The present invention relates to an apparatus for detecting the temperature of a tool during laser-assisted ultrasonic bonding, in particular during laser-assisted ultrasonic wire bonding, comprising an automatic bonding machine having a bonding tool and having a device for exciting the bonding tool to vibrate ultrasonically, comprising a laser generator for providing a laser beam, which heats the bonding tool in particular in the area of the tip of the same, and comprising an optical waveguide for guiding the laser beam from the laser generator to the bonding tool. Furthermore, the invention relates to a method for detecting the temperature of a bonding tool during laser-assisted ultrasonic bonding.

### Description of the Background Art

Usually, in ultrasonic bonding, a bonded connection between two connection partners is established by pressing them against each other using a bonding tool and exciting the bonding tool to vibrate ultrasonically. In addition, it is known to facilitate the connection process by the additional provision of thermal energy. The thermal energy is provided in particular by heating a connection point formed between the connection partners and/or the bonding tool itself with a laser beam.

### SUMMARY OF THE INVENTION

It is therefore an object of the present invention to provide an apparatus and a method for detecting the temperature of a bonding tool during laser-assisted ultrasonic bonding.

To achieve the object, the invention is characterized in that the optical waveguide has a multi-part design, that a deflecting and beam-splitting unit is provided between at least two adjacent parts of the optical waveguide and that a temperature sensor is provided, wherein the deflecting and beam-splitting unit is arranged between the adjacent parts of the optical waveguide and is assigned to the temperature sensor such that the laser beam provided by the laser generator is guided through the first part of the optical waveguide to the deflecting and beam-splitting unit, is deflected by the latter in the direction of a second part of the optical waveguide and is guided through the second part of the optical waveguide to the bonding tool and that, in any case, some of the thermal radiation emitted by the bonding tool as a result of the heating is coupled into the waveguide via an end face of the second part of the optical waveguide, which is facing the tip of the bonding tool, and is fed to the deflecting and beam-splitting unit, and that from there at least some of the coupled-in thermal radiation passes through the deflecting and beam-splitting unit and is incident on the temperature sensor behind it.

The particular advantage of the invention is that by means of the apparatus of the invention, the temperature of the tip of the bonding tool can be directly determined. On the one hand, a (target) temperature for the bonding tool can be set and/or monitored when establishing the bond connection, and, on the other hand, an unacceptably high heating of the bonding tool and/or the connection partners can be prevented. This way, the connection process can be optimized with the result that the cycle times are reduced by the input of thermal energy or that materials can be processed which cannot be bonded reliably without the additional provision of thermal energy.

The apparatus is also simple and compact, since the optical waveguide used to feed the laser beam to the bonding tool simultaneously serves to return some of the thermal radiation emitted by the bonding tool. In this respect, the optical waveguide has a dual function. It guides or leads the laser beam and some of the thermal radiation coupled into the optical waveguide in opposite directions.

The second part of the optical waveguide or some thereof and optionally a beam-forming optical unit can be fixed to a movable bonding head of the automatic bonding machine serving to receive the bonding tool and is moved along during the positioning of the bonding head, whereas the temperature sensor and/or the deflecting and beam-splitting unit and/or the laser generator are arranged in a stationary manner outside the bonding head. This results in low moving masses and good dynamics of the automatic bonding machine, so that short process times are further promoted.

A recess can be provided on the casing side on the bonding tool. An end face of the second part of the waveguide facing the bonding tool is assigned to the recess in such a way that the laser beam escaping the second part of the optical waveguide is incident on a surface of the recess. Advantageously, the provision of the recess on the bonding tool results in good protection against scattered light and thus a precise temperature measurement and, moreover, a good efficiency in the heating of the tip of the bonding tool. The heating is particularly promoted in that the recess acts like a beam trap for the laser light and a reflected part of the laser light again is incident on the surface of the bonding tool formed in the region of the recess. In addition, the provision of the recess enables material in the region of the bonding tool tip to be recessed, so that the tool tip can be heated particularly quickly with the energy provided.

The recess can be provided on the casing side if it is located on a casing side of the bonding tool. The casing side of the bonding tool connects a first end face of the bonding tool with a second end face. The first end face is facing the substrate. It is provided at the tip of the bonding tool. The connection component, for example the bond wire, is applied on the first end face. For example, a long groove for the bond wire is provided on the first end face for this purpose. In the area of the second end face, the bonding tool is fixed to the bonding head. The second end face is opposite the first end face.

The second part of the optical waveguide can be assigned to the bonding tool on the casing side from the outside and is provided at a distance from the bonding tool. Advantageously, this makes the installation of the optical waveguide particularly simple and a contamination of the optical waveguide, especially in the area of the end face facing the bonding tool, is counteracted. In addition, this makes it easy and quick to change the bonding tool. Moreover, the correct position assignment of the bonding tool and optical waveguide can be checked by visual inspection. after the bonding tool has been assembled or changed.

Optionally, a beam-forming optical unit can be provided between the end face of the second part of the optical waveguide facing the bonding tool and the bonding tool. The beam-forming optical unit can, for example, serve as focusing optics for the laser beam. A focal point of the focusing optics may be provided in the recess of the bonding tool and preferably in front of the casing surface of the bonding tool or behind it, i.e., inside the bonding tool. For example, a collimator lens can serve as a beam-forming optical unit. The collimator lens ensures that the divergent laser beam, which is usually decoupled from the waveguide, has an at least approximately parallel beam path after passing through the optical unit. Advantageously, by providing the beam-forming optical units, an unwanted scattering of the laser beam can be counteracted. In addition, the tool can be heated at a given point in a defined way. For example, two or more optical elements, preferably comprising a collimator lens and a focusing lens, can make up the beam-forming optical unit.

The second part of the optical waveguide can be guided in sections in an elongated long channel of the bonding tool which is shaped as a through hole. The long channel ends in the recess. Advantageously, this achieves a very compact design of the apparatus, and the section of the optical waveguide moved with the bonding head is provided in the long channel of the bonding tool where it is protected against ambient influences.

The second part of the optical waveguide can protrude into the recess in sections with the end face facing the bonding tool. Advantageously, this results in a simple way of controlling the correct assembly or arrangement of the optical waveguide in the bonding tool. In addition, the optical waveguide, which is extended into the recess, can be cleaned particularly easily in the area of the end face facing the bonding tool. Furthermore, the coupling of the thermal radiation emitted by the bonding tool into the second part of the optical waveguide is facilitated due to the free accessibility of the end face of the optical waveguide in the area of the recess. In this respect, a sufficient part of the emitted thermal radiation can be reliably fed to the temperature sensor via the optical waveguide and the deflecting and beam-splitting unit.

The temperature sensor can be connected to the laser generator via a communication link, and a control unit is provided, which is designed for operating the laser generator in dependence on the temperature of the bonding tool determined by means of the temperature sensor. Advantageously, by providing the communication link, the laser generator can be operated in a controlled manner. The tip of the bonding tool can thus be heated very specifically and precisely, and damage to the bonding tool or the connection partners can be reliably avoided.

Optionally, it may be provided that a further communication link can be provided between the automatic bonding machine and the temperature sensor. Via the communication link, for example, information on the bonding process can be made available and forwarded to the control unit.

A collimator can be assigned to an end face of the first optical waveguide facing the deflecting and beam-splitting unit. By providing the collimator it is ensured that the laser beam exiting from the first part of the optical waveguide has an almost completely parallel beam path and is incident on the deflecting and beam-splitting unit in a defined manner. As a result, a high optical efficiency is realized with the consequence that the heating of the bonding tool can be performed in a defined and predetermined manner. The coupling of the laser beam after deflection into the second part of the optical waveguide can be done via a lens.

A wavelength of the laser beam can differ significantly from a wavelength of the thermal radiation that is emitted by the bonding tool and/or fed to the temperature sensor for evaluation. Overlap areas of the wavelengths involved are reliably avoided by designing the temperature sensor for a wavelength in the range of 1500 nm to 15000 nm and preferably in the range of 1800 nm to 2100 nm and particularly preferably of 2000 nm, whereas the laser generator provides a laser beam with a wavelength in the range of 200 nm to 1200 nm and preferably of 1070 nm. A falsification of the temperature measurement can thus be very reliably prevented.

As an optical waveguide for the laser beam and/or the thermal radiation, for example, a glass fiber or a glass fiber bundle may be provided. For example, a plastic or a glass rod may be provided as an optical waveguide. For example, a tube or a flexible hose can serve as an optical waveguide. Optionally, the optical waveguide can provide a reflection coating for the realization of total reflection, at least in sections of the casing side. As a result, radiation (laser beam and/or thermal radiation) can be guided particularly effectively in the optical waveguide. The reflection coating may be designed in such a way, for example, that in particular radiation having the special wavelength is reflected with low loss by the optical guide and is passed through the optical guide.

Temperature of the bonding tool in laser-assisted ultrasonic bonding can be detected by heating the bonding tool in particular at its tip by means of a laser beam, which is provided by a laser generator and fed to the bonding tool by means of an optical waveguide. According to the invention, the laser generator is operated when establishing the bond connection in order to heat the tip of the bonding tool to a target temperature in the range of 200° C. to 600° C. In any case, the temperature of the bonding tool is detected during establishment of the bond connection and preferably continuously throughout the bonding process.

The particular advantage of the invention is that the heating of the tip of the bonding tool by means of the laser beam can be simultaneously carried out quickly and effectively, and yet unacceptably high heating and ultimately damage to the bonding tool and/or the connection partners is effectively prevented.

The temperature at the tip of the bonding tool can be determined in that thermal radiation emitted by the bonding tool is fed to a temperature sensor via the optical waveguide, which is used to feed the laser beam. Advantageously, the temperature determination can be carried out exactly or precisely by using the emitted thermal radiation and the supply of the same by the optical waveguide to the temperature sensor. In addition, there is no need for a direct spatial assignment of the temperature sensor to the bonding tool. The optical waveguide also connects the bonding tool to the temperature sensor over a greater distance. Said sensor can be provided remotely from the bonding tool. In particular, it is not necessary for the temperature sensor to be moved with the bonding tool or to follow a movement of the bonding tool or to be aligned with the bonding tool.

The laser beam provided by the laser generator and the thermal radiation coupled into the optical waveguide can be fed to a common deflecting and beam-splitting unit, wherein the laser beam is deflected by the deflecting and beam-splitting unit and at least some is coupled into the optical waveguide, whereas at least some of the thermal radiation coupled into the optical waveguide passes through the deflecting and beam-splitting unit and then is incident on the temperature sensor. Advantageously, by using the common deflecting and beam-splitting unit, the complexity of the apparatus that is necessary for the execution of the inventive method can be reduced. In this respect, the deflecting and beam-splitting unit, like the optical waveguide, has a dual function with regard to the deflection of the laser beam on the one hand and the filtering or decoupling of the thermal radiation on the other.

According to an example, it may be provided that the laser generator provides the laser beam exclusively during establishment of the bond connection. In the other phases of the bonding process, such as when positioning the bonding tool, the laser generator may be deactivated. In this respect, the laser generator can be operated cyclically.

In particular, it may be provided that the bonding tool can be heated by means of the laser beam before or while it is pressed against the connection partners and/or is excited to ultrasonically vibrate.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a schematic diagram of an inventive apparatus for detecting the temperature of a bonding tool during laser-assisted ultrasonic bonding in an example embodiment,

FIG. 2 is a detailed enlargement of the tip of a bonding tool of the apparatus according to FIG. 1 designed for ultrasonic wire bonding,

FIG. 3 is a schematic diagram of the apparatus of the invention for detecting the temperature of the bonding tool during laser-assisted ultrasonic bonding in a second embodiment,

FIG. 4a is a schematic diagram of a first variant of the assignment of the optical waveguide to the bonding tool,

FIG. 4b is a side view of the tip of the bonding tool according to the first variant of the assignment as a variant with a passage recess,

FIG. 5a is a schematic diagram of a second variant of the assignment of the optical waveguide to the bonding tool,

FIG. 5b is a side view of the tip of the bonding tool according to the second variant of the assignment as a variant with a passage recess,

FIG. 6a is a schematic diagram of a third variant of the assignment of the optical waveguide to the bonding tool,

FIG. 6b is a side view of the tip of the bonding tool according to the third variant of the assignment as a variant with a passage recess,

FIG. 7 is a schematic diagram of a fourth variant of the assignment of the optical waveguide to the bonding tool, and

FIG. 8 is a beam-forming optical unit of the apparatus of the invention having two lenses.

### DETAILED DESCRIPTION

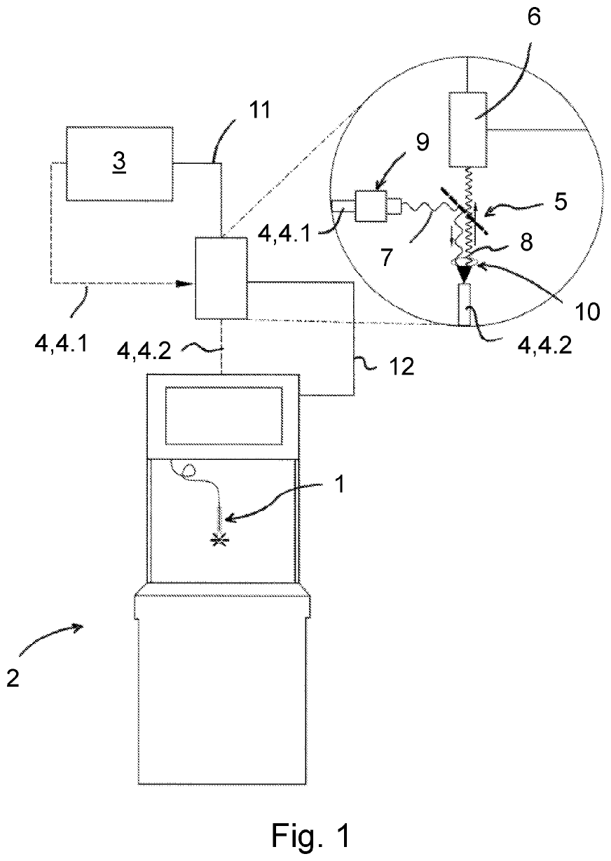

An inventive apparatus for detecting the temperature of a bonding tool 1 during laser-assisted ultrasonic bonding according to FIG. 1 comprises an automatic bonding machine 2 having the bonding tool 1 and having an apparatus for exciting the bonding tool to ultrasonically vibrate and a displacement and/or positioning module, for the bonding tool 1. Furthermore, it comprises a laser generator 3 for providing a laser beam 7 as well as an optical waveguide 4 for guiding the laser beam 7 from the laser generator 3 to the bonding tool 1. The optical waveguide 4 has a multi-part design. Between two adjacent parts 4.1, 4.2 of the optical waveguide 4, a deflecting and beam-splitting unit 5 is provided. Furthermore, a temperature sensor 6 is comprised, which is data-technically connected to the laser generator 3 by means of a communication link 11 and to the automatic bonding machine 2 by means of another communication link 12.

The deflecting and beam-splitting unit 5 is assigned to a first part 4.1 and a second part 4.2 of the optical waveguide 4 in such a way that the laser beam 7 decoupled from the first part 4.1 of the optical waveguide 4 is incident on the deflecting and beam-splitting unit 5 and is deflected from there in the direction of the second part 4.2 of the optical waveguide 4. A collimator 9 is assigned to the end face of the first part 4.1 of the optical waveguide 4, which is facing the deflecting and beam-splitting unit 5. The collimator 9 ensures that the laser beam 7 provided by the laser generator 3 has an almost completely parallel beam path. The deflected laser beam 7 is then coupled into the second part 4.2 of the optical waveguide 4 via a lens 10 and is fed to the tool 1.

The second part 4.2 of the optical waveguide 4 also serves to guide thermal radiation 8 emitted by the bonding tool 1 to the temperature sensor 6. In the second part 4.2 of the optical waveguide 4, the laser beam 7 and the thermal radiation 8 are therefore guided in opposite directions, or counterposed. The thermal radiation 8 is guided via the second part 4.2 of the optical waveguide to the deflecting and beam-splitting unit 5. Depending on the wavelength of the thermal radiation 8, this passes through the deflecting and beam-splitting unit 5 and is incident on the temperature sensor 6 behind the deflecting and beam-splitting unit 5.

In the present embodiment of the invention, thermal radiation having a wavelength in the range of 2000 nm is used by the temperature sensor to determine the temperature of the bonding tool 1.

The temperature sensor 6 is connected to the laser generator 3 via a communication link 11. As a communication link 11, for example, a data line may be provided. For example, communication can be wireless. Via the communication link 11, the temperature sensor 6 can interact, for example, with a not-shown control unit. The laser generator 3 can be operated in regular operation. In this way, it can be ensured that neither the bonding tool 1 nor the connection partners are inadmissibly heated and/or damaged. In particular, the formation of a melt during connection of the connecting partners is prevented. In addition, it has been shown that the bonding results are constant or easily reproducible and that differences in the substrate can be better compensated.

The temperature sensor 6 is connected to the automatic bonding machine 2 via an additional communication link 12. For example, process data for the bonding process can be provided via the additional communication link 12. The additional communication link 12 can be designed, for example, as a data line, or communication takes place wirelessly.

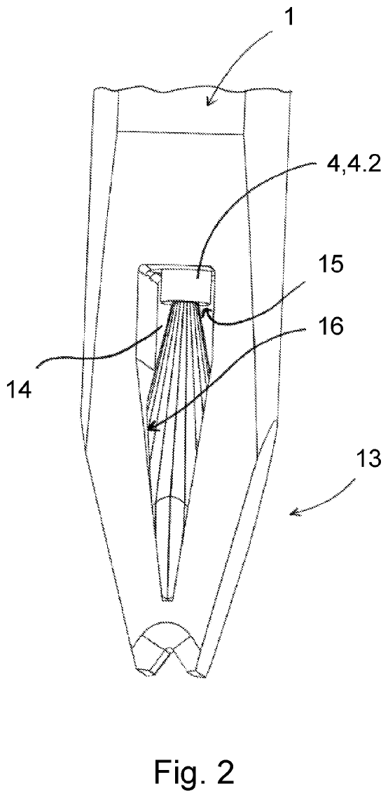

The bonding tool 1 of the inventive apparatus is shown in FIG. 2 in excerpts. It is formed by way of example as a wedge for ultrasonic wire bonding. The bonding tool 1 is elongated and slim, having a tool shaft and the tip 13 connected to the tool shaft. On the end face in the area of the tool tip 13, an approximately V-shaped notch is formed, which serves to accommodate and guide a bond wire. In the direction of the notch, the bonding tool 1 tapers in the shape of a wedge.

The bonding tool 1 provides a long channel for the second part 4.2 of the optical waveguide 4, which extends along the inner side of a shaft of the bonding tool and ends in a recess 14 that is formed at the tip 13 of the bonding tool. The second part 4.2 of the optical waveguide 4 is guided through the long channel up to the recess 14 of the bonding tool 1 in such a way that an end face 15 of the second part 4.2 of the optical waveguide 2 facing the bonding tool 1 is provided in the recess 14.

The laser beam 7, which is decoupled from the optical waveguide 4, is incident on a surface area 16, which is formed in the area of the recess 14 on the bonding tool 1. The recess 14 is formed in the manner of a beam trap by means of laser light 7 in such a way that a reflected part of the laser beam 7 is again incident on the surface 16 after reflection. In this respect, the tip 13 of the bonding tool 1 can be a particularly effectively heated.

The thermal radiation 8 emitted by the bonding tool 1 as a result of heating its tip 13 is in part incident on the end face 15 of the optical waveguide 4. Above the second part 4.2 of the optical waveguide 4, the coupled-in part of the thermal radiation 8 is guided to the deflecting and beam-splitting unit 5. Thermal radiation 8 of the wavelength of 2000 nm then passes through the deflecting and beam-splitting unit 5 and is incident on the temperature sensor 6 behind it. The portion of the thermal radiation 8 that is incident on the temperature sensor 6 is used to determine the temperature of the tip 13 of the bonding tool 1.

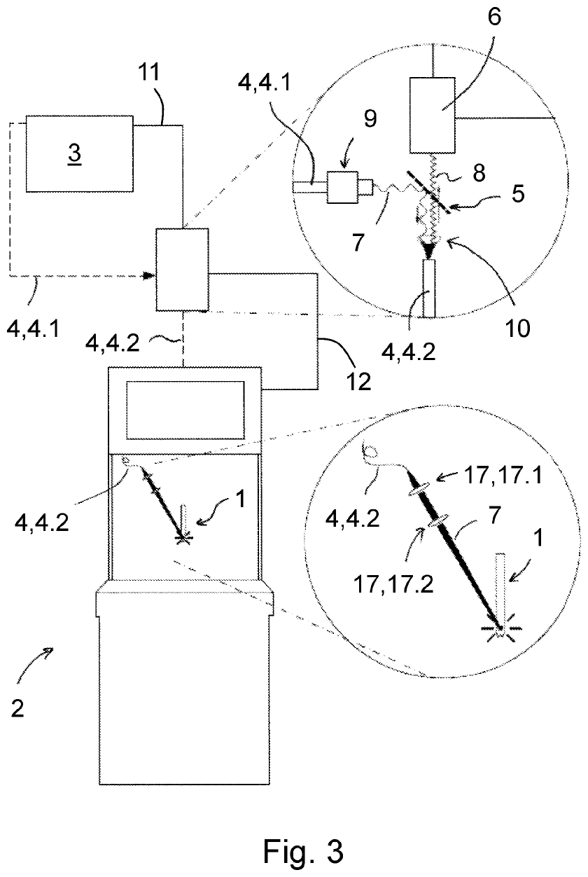

According to a second embodiment of the invention per FIG. 3, the second part 4.2 of the optical waveguide 4 is assigned to the casing side of the bonding tool 1 from the outside. The assignment is carried out in such a way that the laser beam 7 decoupled from the second part 4.2 of the optical waveguide 4 and located on the end face 15 facing the bonding tool 1 is directed to the recess 14, which is provided on the casing side of the bonding tool 1 and is incident there on the bonding tool 1 to heat it. The recess 14 also serves as an absorption area here. As usual, it is formed as a beam trap for the laser beam 14 and is, in any case, partially provided in the area of the tip 13 of the bonding tool 1.

In the beam path of the laser beam 7, a beam-forming optical unit 17 is arranged between the end face 15 of the second part 4.2 of the optical waveguide 4 and the bonding tool 1. By way of example, the beam-forming optical unit is formed by two lenses 17.1, 17.2 that are spaced from another, through which the laser beam 7 passes sequentially.

Some of the thermal radiation 8 emitted by the bonding tool 1 as a result of the heating passes through the beam-forming optical unit 17 like the laser beam 7 and is then coupled into the second part 4.2 of the optical waveguide 4 via the end face 15 of the deflecting and beam-splitting unit 5 and guided to the deflecting and beam-splitting unit 5. From there, in any case, some of the thermal radiation 8 coupled into the optical waveguide 4 reaches the temperature sensor 6 by bypassing the first part 4.1 of the optical waveguide 4.

The processing of the measured values of the temperature sensor 6 and the operation of the laser generator 3 are carried out in the manner described above.

The laser generator 3, the deflecting and beam-splitting unit 5, the temperature sensor 6 and the first part 4.1 of the optical waveguide 4 are preferably arranged in a stationary manner. On the other hand, the beam-forming optical unit 17 and the second part 4.2 of the optical waveguide 4 are, at least in sections, fixed to the bonding head of the automatic bonding machine. Advantageously, the masses moved when positioning the bonding tool held on the bonding head 1 are low, with the consequence that the automatic bonding machine has good dynamic properties and that, in particular, a fast (re-) positioning of the bonding head is made possible.

According to the second embodiment of the invention, it can be dispensed with providing a long channel on the bonding tool 1. The end face 15 of the second part 4.2 of the optical waveguide 4 facing the bonding tool 1 is preferably provided outside the recess 14 and distanced from the bonding tool 1.

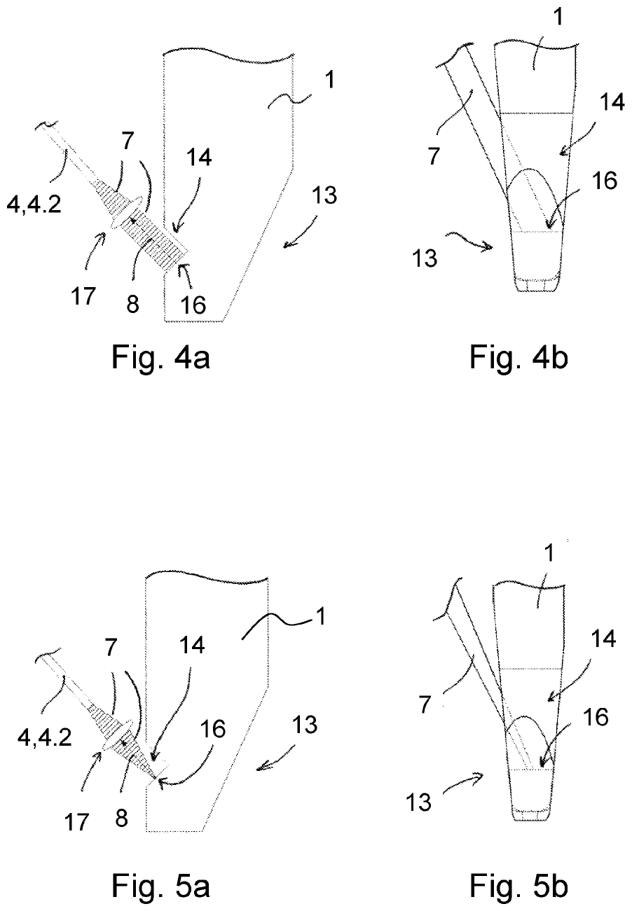

FIGS. 4a to 6b show different variants of the external assignment of the optical waveguide 4 to the bonding tool 1 or different variants of the beam-forming optical unit 17.

According to a first variant per FIGS. 4a and 4b, the second part 4.2 of the optical waveguide 4 is assigned to the bonding tool 1 diagonally from above. In the beam path of the divergent laser beam 7 decoupled from the optical waveguide 4 there is a collimator lens 17. After passing through the collimator lens 17, the laser beam 7 has an essentially parallel beam path. The laser beam 1 then is incident on the recess 14 formed on the casing side of the bonding tool 1.

Also, some of the thermal radiation 8 emitted by the bonding tool 1 passes through the optical unit 17 before it is coupled, via the end face 15 facing the bonding tool 1 and the optical unit 17, into the second part 4.2 of the optical waveguide 4 and fed to the temperature sensor 6.

A similar configuration is shown in FIGS. 5a and 5b. Here, it is the case that the beam-forming optical unit 17 provides a focusing lens. A focal point of the focusing optical unit 17 may be provided in the recess 14 of the bonding tool 1 and preferably in front of the surface 16 of the recess 14 or behind it, that is, in the interior of the bonding tool 1.

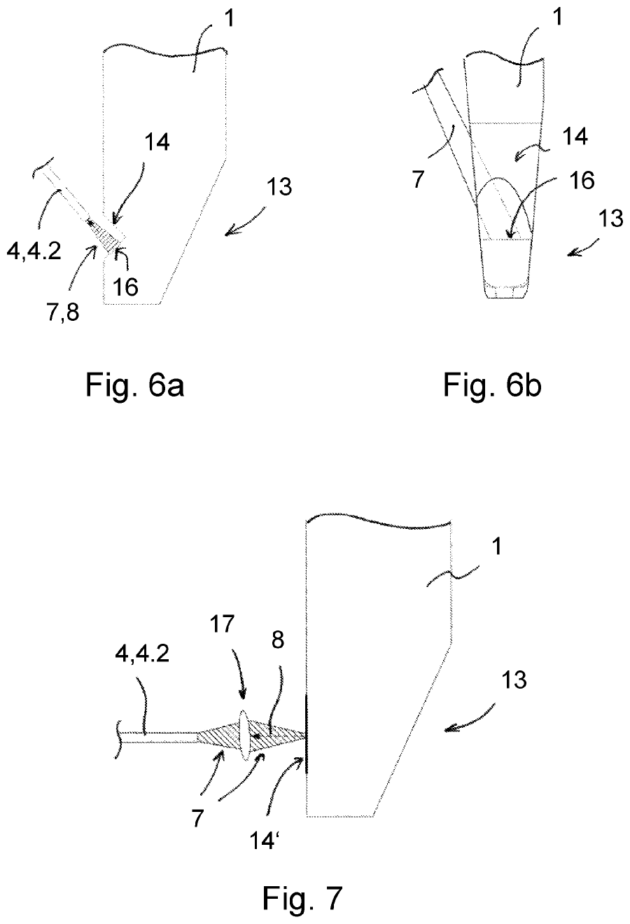

Alternatively, as shown in FIGS. 6a and 6b, a beam-forming optical unit can be dispensed with. The divergent laser beam 7 escaping from the second part 4.2 of the optical waveguide 4 then is incident on the bonding tool 1 in the area of the recess 14.

In FIGS. 4b, 5b and 6b, the bonding tool 2 or the tip 5 of a bonding tool 2 for ultrasonic thick wire bonding is shown in a side view. In the exemplary embodiments, a preferably V-shaped long groove is formed on the first end face of the bonding tool 1. The long groove is used to accommodate a bond wire, in particular an aluminum or copper wire in ultrasonic thick wire bonding. However, the discussion of the invention using the example of ultrasonic thick wire bonding is only exemplary. The invention can certainly also be used in other laser-assisted ultrasonic bonding processes, for example in ultrasonic thin wire bonding, chip bonding or ribbon bonding.

According to the invention, the recess 14 may either be pocket-shaped or formed as a passage recess. FIGS. 4a, 5a and 6a show the recess 14 provided on the casing side of the bonding tool 1 designed as a pocket. The recess 14 is not continuous, i.e., is trough-shaped. In contrast, the recess 14 in FIGS. 4b, 5b and 6b is realized by way of example in the manner of a passage recess.

Alternatively, according to the invention, the provision of a recess on the bonding tool 1 can be dispensed with. FIG. 7 shows a bonding tool 1 without a recess. On the bonding tool 1, an absorption range 14′ is formed. The laser beam 7 guided from outside to the bonding tool 1 is incident on the bonding tool 1 in the absorption range 14′ and heats it. For example, the bonding tool 1 in the absorption range 14′ may have a coating which—based on a wavelength of the laser beam 7—is formed from a particularly well absorbent material, in particular titanium. For example, on the surface of the bonding tool 1 in the absorption range 14′, local microstructures can be provided to improve the absorption capability.

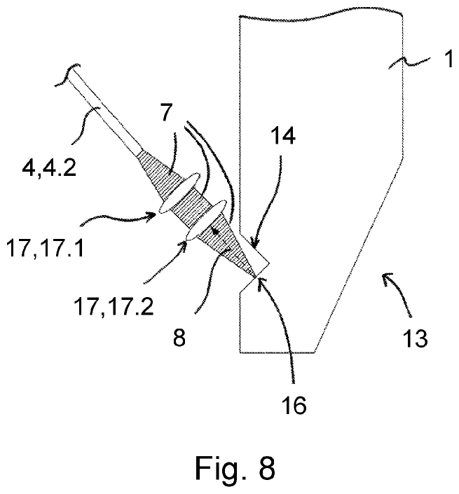

As an example, FIG. 8 shows that the beam-forming optical unit 17 provides a collimator lens 17.1 and a focusing lens 17.2. The divergent laser beam 7 escaping from the optical waveguide 4 initially is incident on the collimator lens 17.1 and has an essentially parallel beam path after passing through the collimator lens 17.1. The laser beam 7 with the essentially parallel beam path then is incident on the focusing lens 17.2 and is focused.

The same components and component functions are identified by the same reference signs.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An apparatus for detecting a temperature of a bonding tool during laser-assisted ultrasonic bonding, the apparatus comprising:
an automatic bonding machine having the bonding tool, having a displacement and/or positioning module for the bonding tool and having a device for exciting the bonding tool to ultrasonically vibrate;
a laser generator to provide a laser beam;
an optical waveguide to guide the laser beam from the laser generator to the bonding tool, the optical waveguide having a multi-part design;
a deflecting and beam-splitting unit provided between at least two adjacent parts of the optical waveguide; and
a temperature sensor,
wherein the deflecting and beam-splitting unit is arranged between the adjacent parts of the optical waveguide and is assigned to the temperature sensor such:
that the laser beam provided by the laser generator is guided through the first part of the optical waveguide to the deflecting and beam-splitting unit, then is incident on the deflecting and beam-splitting unit and there is deflected in a direction of a second part of the optical waveguide and is guided through the second part of the optical waveguide to the bonding tool and the bonding tool is heated; and
that a portion of the thermal radiation emitted by the bonding tool as a result of the heating is coupled into the second part of the waveguide via an end face of the second part of the optical waveguide that is facing the bonding tool, and is fed to the deflecting and beam-splitting unit; and
that at least some of the coupled-in thermal radiation passes through the deflecting and beam-splitting unit and then is incident on the temperature sensor.

2. The apparatus according to claim 1, wherein a collimator is assigned to an end face of the first part of the optical waveguide facing the deflecting and beam-splitting unit such that the laser beam is incident on the deflecting and beam-splitting unit with an at least essentially parallel beam path.

3. The apparatus according to claim 1, wherein the temperature sensor is connected to the laser generator via a communication link and wherein a control unit interacting with the temperature sensor and/or the laser generator is provided for operating the laser generator in dependance on the temperature of the bonding tool that is determined via the temperature sensor.

4. The apparatus according to claim 1, wherein a recess is formed on a casing side of the bonding tool and wherein an end face of the second part of the optical waveguide facing the bonding tool is assigned to the recess such that the laser beam escaping from the second part of the optical waveguide is incident on an upper surface of the recess.

5. The apparatus according to claim 1, wherein the second part of the optical waveguide is guided in sections in a long channel of the bonding tool and wherein the long channel ends in the recess.

6. The apparatus according to claim 5, wherein the optical waveguide is assigned to the bonding tool such that the second part of the optical waveguide protrudes end-side into the recess and/or the end face of the optical waveguide facing the bonding tool is provided in the recess and outside the long channel.

7. The apparatus according to claim 1, wherein the second part of the optical waveguide is assigned to the bonding tool from outside and/or wherein the second part of the optical waveguide is spaced at a distance from the bonding tool and/or wherein the second part of the optical waveguide, at least in sections, is fixed to a bonding head of the automatic bonding machine serving to receive and position the bonding tool and is moved along with the bonding head when it is displaced.

8. The apparatus according to claim 1, wherein a head end of the second part of the optical waveguide is assigned a beam-forming optical unit such that a beam path is formed from the laser beam escaping from the second part of the optical waveguide.

9. The apparatus according to claim 1, wherein the deflecting and beam-splitting unit and/or the laser generator and/or the collimator and/or the temperature sensor are arranged in a stationary manner outside the bonding head and/or wherein the beam-forming optical unit is fixed on the bonding head and moved along with the bonding head when this is displaced.

10. The apparatus according to claim 1, wherein the temperature sensor has a wavelength measuring range of 1500 nm to 15000 nm or of 1800 nm to 2100 nm.

11. The apparatus according to claim 1, wherein the laser beam provided by the laser generator has a wavelength in the range of 200 nm to 1200 nm or of 1070 nm.

12. A method for detecting a temperature of a bonding tool during laser-assisted ultrasonic bonding, the method comprising:
heating the bonding tool at least in an area of a tip of the bonding tool via a laser beam;
providing the laser beam by a laser generator;
directing the laser beam towards the bonding tool via an optical waveguide;
detecting the temperature of the bonding tool at the tip of the bonding tool; and
operating the laser generator during establishment of the bond connection until the tip of the bonding tool has a target temperature in a range of 200° C. to 600° C.

13. The method according to claim 12, wherein the temperature of the tip of the bonding tool is determined in that thermal radiation emitted by the bonding tool is coupled into the optical waveguide and fed via the optical waveguide to a temperature sensor.

14. The method according to claim 12, wherein the laser beam provided by the laser generator and the thermal radiation coupled into the optical waveguide are fed to a common deflecting and beam-splitting unit, wherein the laser beam is deflected by the deflecting and beam-splitting unit in a direction of the bonding tool and wherein at least a portion of the thermal radiation coupled into the optical waveguide passes through the deflecting and beam-splitting unit and then is incident on the temperature sensor.
